(19) United States
(12) Patent Application Publication
(10) Pub. No.: US 2011/0011636 A1
(43) Pub. Date: Jan. 20, 2011

(54) Multilayer wiring board and method of manufacturing the same

(75) Inventors: Kwang Jae Oh, Suwon (KR); Joo Yong Kim, Seongnam (KR); Yoon Hyuck Choi, Yongin (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/654,491

(22) Filed: Dec. 22, 2009

(30) Foreign Application Priority Data
Jul. 17, 2009 (KR) 10-2009-0065536

(51) Int. Cl. H05K 1/16; H05K 3/30

(52) U.S. Cl. 174/260; 29/832; 29/610.1; 29/850

(57) ABSTRACT

There are provided a multilayer wiring board and a method of manufacturing the same. The multilayer wiring board according to an aspect of the invention may include: a main body having a plurality of insulting layers stacked upon each other, including a first layer provided as an inner layer and a second layer provided as an outer layer; a first resistor provided on the first layer; and a second resistor provided on the second layer, connected in parallel with the first resistor, and having a smaller area than the first resistor. The multilayer wiring board obtains a target resistance value using the first and second resistors formed on the first and second layers. The second resistor, formed on the outer layer, can have a smaller area than the first resistor. Accordingly, the usable area of the outer layer is increased to thereby reduce the size of the multilayer wiring board.

### CROSS-REFERENCE TO RELATED APPLICATIONS

This application claims the priority of Korean Patent Application No. 10-2009-0065536 filed on Jul. 17, 2009, in the Korean Intellectual Property Office, the disclosure of which is incorporated herein by reference.

### BACKGROUND OF THE INVENTION

1. Field of the Invention

The present invention relates to a multilayer wiring board and a method of manufacturing the same, and more particularly, to an embedded resistor multilayer wiring board allowing for size reduction and a method of manufacturing the same.

2. Description of the Related Art

In order to manufacture electronic products with reduced size and increased functionality in line with the recent developments in the electronics industry, technologies in electronics industry are being developed so that resistors, capacitors, integrated circuits and the like may be inserted into boards.

Currently, in most cases, general discrete chip resistors or general discrete chip capacitors are mounted on the surface of printed circuit boards. Recently, the development of printed circuit boards embedded with passive elements, such as resistors or capacitors, has been conducted.

That is, according to the technology for manufacturing printed circuit boards embedded with passive elements, passive elements are inserted into the inside and outside of printed circuit boards by a process using new materials to thereby replace existing chip resistors or existing chip capacitors.

Among the above-described printed circuit boards embedded with passive elements, when resistors are printed on the inside or the outside of printed circuit boards and are integrated into the printed circuit boards as components thereof regardless of the size of the printed circuit boards, these resistors are referred to as embedded (buried) resistors, and these boards are referred to as embedded resistor printed circuit boards.

Since this embedded resistor printed circuit board already includes resistors as apart forming the printed circuit board, there is no need to mount a separate chip resistor onto the surface of the printed circuit board.

Examples of a method of mounting a resistor onto a printed circuit board may include screen printing, plating, and using a sheet.

When a large amount of power is applied to an embedded resistor printed circuit board, the characteristics thereof may be deteriorated due to heat consumed by resistors. The power is used by printing a wide resistor pattern in order to prevent the deterioration of the resistors. However, an increase in the area of the resistor may cause an increase in the size of the board, thereby weakening price competitiveness and preventing a reduction in board size.

### SUMMARY OF THE INVENTION

An aspect of the present invention provides a multilayer wiring board and a method of manufacturing the same that can achieve size reduction by increasing the usable area of an outer layer.

According to an aspect of the present invention, there is provided a multilayer wiring board including: a main body having a plurality of insulting layers stacked upon each other, including a first layer provided as an inner layer and a second layer provided as an outer layer; a first resistor provided on the first layer; and a second resistor provided on the second layer, connected in parallel with the first resistor, and having a smaller area than the first resistor.

The second resistor may have a greater resistance value than the first resistor.

The second resistor may have a resistance value adjustment portion.

The first layer may include an inner layer circuit pattern electrically connected to the first resistor, the second resistor may include an outer layer circuit pattern electrically connected to the second resistor, and the inner layer circuit pattern and the outer layer circuit pattern may be electrically connected to each other through via holes.

According to another aspect of the present invention, there is provided a method of manufacturing a multilayer wiring board, the method including: providing a plurality of insulating layers forming a main body; forming a first resistor on a first layer provided as an inner layer among the insulating layers; forming a second resistor on a second layer provided as an outer layer among the insulating layers while the second resistor may have a smaller area than the first resistor; and stacking the first and second layers so that the first and second resistors are connected in parallel with each other.

The second resistor may have a greater resistance value than the first resistor.

The method may further include obtaining a target resistance value by trimming the second resistor after stacking of the first and second layers.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic exploded perspective view illustrating a multilayer wiring board according to an exemplary embodiment of the present invention;

FIG. 2 is a schematic sectional view taken along the line I-I′ of the multilayer wiring board of FIG. 1;

FIG. 3 is a circuit diagram illustrating first and second resistors according to an exemplary embodiment of the present invention; and

FIGS. 4A through 4F are cross-sectional views illustrating a method of manufacturing a multilayer wiring board according to an exemplary embodiment of the present invention.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals will be used throughout to designate the same or like components.

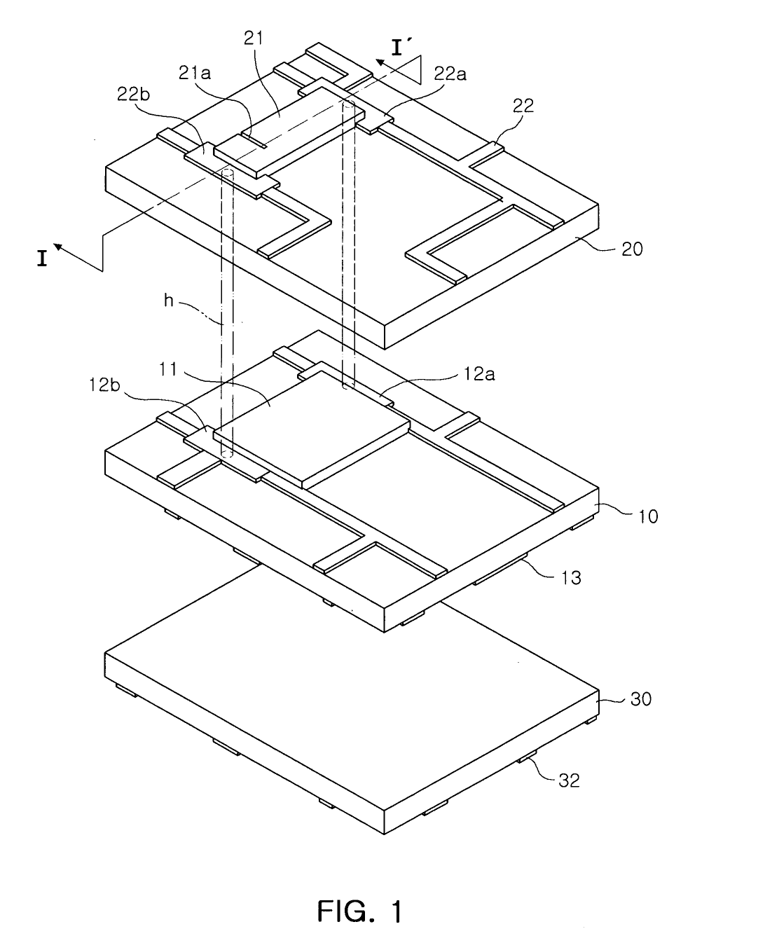

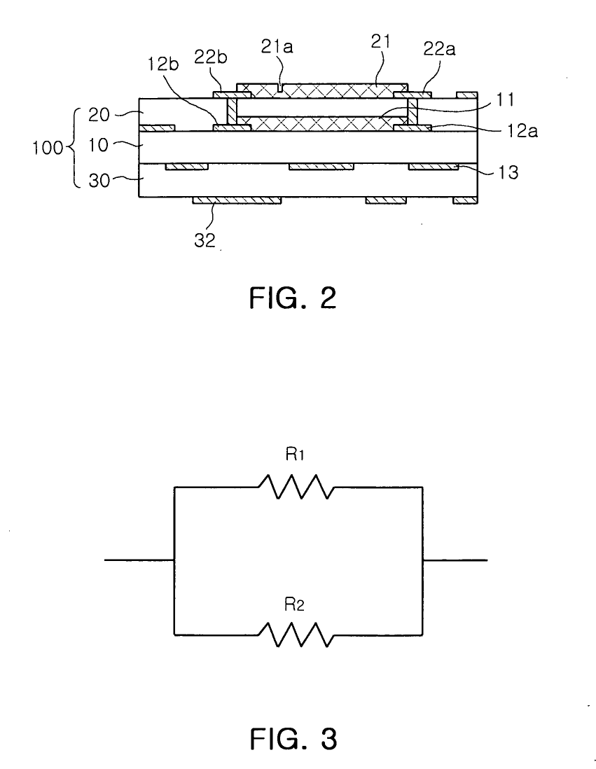

FIG. 1 is a schematic exploded perspective view illustrating a multilayer wiring board according to an exemplary embodiment of the invention. FIG. 2 is a schematic sectional view taken along the line I-I′ of the multilayer wiring board of FIG. 1.

Referring to FIGS. 1 and 2, a multilayer wiring board according to this embodiment is formed by stacking a plurality of insulating layers 10, 20 and 30 upon one another. The multilayer wiring board includes a main body 100 having the first layer 10 as an inner layer and a second layer 20 as an outer layer, a first resistor 11 formed on the first layer 10, and a second resistor 21 formed on the second layer 20, connected in parallel with the first resistor 11, and having a smaller area than the first resistor 11.

Each of the first and second resistors has a length in which currents flow and a width in a direction perpendicular to the direction in which the currents flow.

The main body 100 of the multilayer wiring board is formed by stacking a plurality of insulating layers, including the first layer 10 as an inner layer and the second layer 20 as an outer layer. The main body 100 may further include the third layer 30 as another outer layer that is formed on the other side of the first layer 10 opposite to one side thereof on which the second layer 20 is formed. Though not shown in the drawings, a plurality of insulating layers may be stacked between the first layer 10 and the second layer 20.

The plurality of insulating layers 10, 20 and 30 forming the main body 100 may be insulating resin layers or ceramic layers. Insulating resin has excellent electrical insulation properties, yet it has insufficient mechanical stiffness and undergoes significant changes in dimensions (thermal expansion coefficient) with temperature. In order to overcome these disadvantages, reinforcements, such as paper, fiberglass or organic non-woven fabric, may be mixed with insulating resin.

The first resistor 11 is formed on the first layer 10, which is provided as an inner layer of the main body 100. An inner layer circuit pattern 12 is formed on the first layer 10. The first resistor 11 is electrically connected to the inner layer circuit pattern 12. The inner layer circuit pattern 12 includes first and second inner layer pads 12a and 12b. As shown in FIGS. 1 and 2, both ends of the first resistor 11 may be connected to the first and second inner layer pads 12a and 12b.

The second resistor 21 is formed on the second layer 20, which is provided as an outer layer of the main body 100.

An outer layer circuit pattern 22 is formed on the second layer 20, and the second resistor 21 is electrically connected to the outer layer circuit pattern 22. The outer layer circuit pattern 22 includes first and second outer pads 22a and 22b. As shown in FIGS. 1 and 2, both ends of the second resistor 21 may be connected to the first and second outer pads 22a and 22b.

The first and second outer pads 22a and 22b may be connected to the first and second inner layer pads 12a and 12b , respectively, through via holes.

However, a parallel connection between the first resistor 11 and the second resistor 21 is not limited thereto. Though not shown in the drawings, a parallel connection therebetween can be made through an electrical connection between one region of the inner layer circuit pattern connected to the first resistor 11 and one region of the outer layer circuit pattern connected to the second resistor 21.

The second resistor 21 is connected in parallel with the first resistor 11 and has a smaller area than the first resistor 11.

As shown in the drawings, the first and second resistors 11 and 21 have the same length while the first resistor 11 may have a larger width than the second resistor 21.

In this embodiment, in order to obtain a desired resistance value, the first and second resistors are formed and connected in parallel with each other. That is, the first and second resistors are formed on the inner and outer layers, respectively, so that the second resistor, formed on the outer layer, has a smaller area than the first resistor formed on the inner layer. As the area of the second resistor formed on the outer layer is reduced, it is possible to increase the usable area of the outer layer.

In the related art, if large currents flow, a resistor having a large area is printed on an outer layer in order to prevent the deterioration of the resistor. However, the resistor having the large area takes up a large area of the substrate surface, which may increase the size of the entire substrate or reduce the area of the substrate in which other elements are mounted. As a result, price competitiveness is reduced, and a reduction in product size is limited.

However, the multilayer wiring board according to this embodiment has the second resistor, which is formed on the outer layer and has a smaller area than the first resistor, which increases the area of the outer layer where other elements are mounted, thereby increasing the utilization of the substrate area.

One resistor may be formed on the outer layer in order to increase the area utilization of the substrate, while the first resistor may include a plurality of resistors. In addition, though not shown, the inner layer may include a plurality of layers.

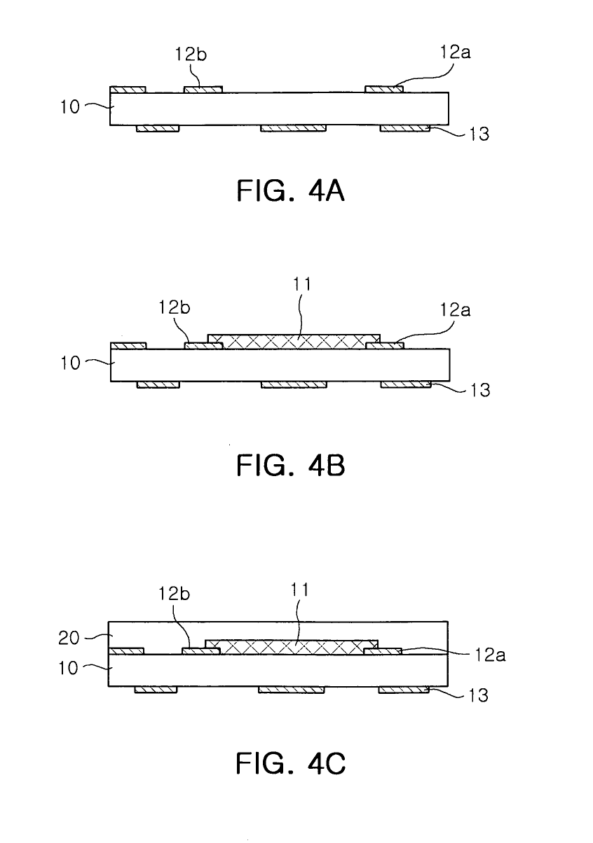

FIG. 3 is a circuit diagram illustrating first and second resistors according to an exemplary embodiment of the invention. As shown in FIG. 3, the first and second resistors are connected in parallel with each other. A target resistance value R satisfies the following equation:

$$\frac{1}{R} = \frac{1}{{R}_{1}} + \frac{1}{{R}_{2}} . \qquad Equation$$

A resistance value R₂ of the second resistor may be larger than a resistance value R₁ of the first resistor. Most of the currents flowing through the multilayer wiring board flow through the first resistor 11 having a small resistance value, while a part of the currents flows through the second resistor 21. The currents flowing through the multilayer wiring board are thereby spread to prevent the deterioration of the resistors.

In order to more accurately obtain a target resistance value, the second resistor 21 may have a resistance value adjustment portion 21a.

The second resistor 21 is formed on the second layer 20 as the outer layer of the main body 100 forming the multilayer wiring board. The second resistor 21 is appropriate for obtaining a target resistance value.

The resistance value adjustment portion of the second resistor 21 is not particularly limited. For example, the second resistor undergoes trimming to adjust the resistance value R₂ of the second resistor.

More specifically, the second resistor 21 is formed to have a resistance value smaller than the target resistance value. Then, probes connected to a resistance measurement device are connected to electrodes of both ends of the second resistor 21 to thereby measure a resistance value in real time and at the same time, perform laser machining on the second resistor to thereby obtain a target resistance value.

Since the target resistance value is obtained through the second resistor 21, the first resistor 11, formed on the inner layer, does not require an area where a resistance value adjusting process, such as a trimming process, is performed. Therefore, a decrease in the effective area in consideration of a trimming process can be prevented.

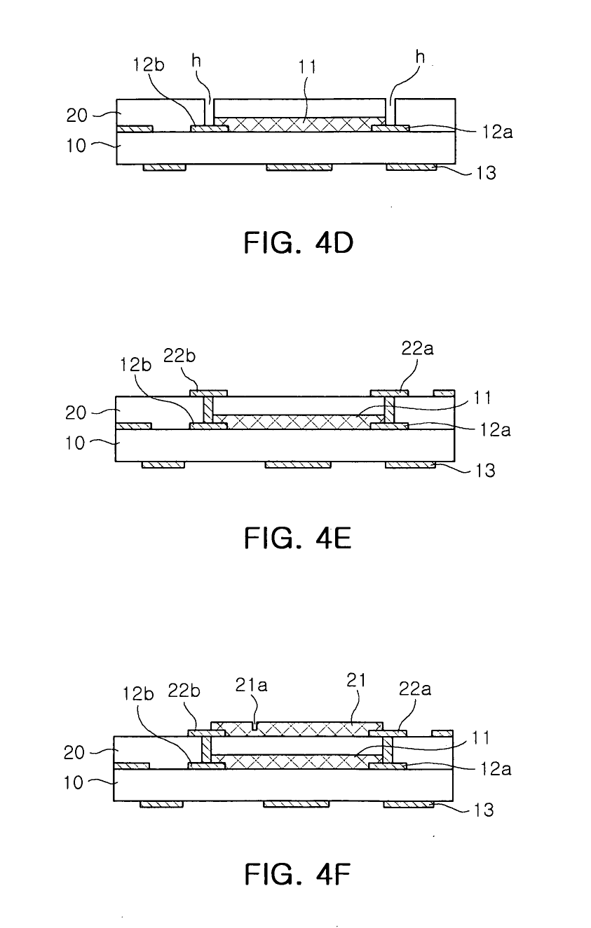

FIGS. 4A through 4F are cross-sectional views illustrating a method of manufacturing a multilayer wiring board according to an exemplary embodiment of the invention.

As shown in FIG. 4A, the inner layer circuit pattern 12 having the first and second inner layer pads 12a and 12b is formed on the first layer 10 of an insulating material. The first layer 10 is provided as an inner layer of the main body of the multilayer wiring board.

Another inner layer circuit pattern 13 may be formed on the other side of the first layer 10 on which the inner layer circuit pattern is formed. As described above, the first layer 10 may be an insulating resin layer or a ceramic layer.

A method of forming the inner layer circuit patterns 12 and 13 is not particularly limited. For example, when the first layer 10 is an insulating resin layer, a conductive layer is formed on the insulating resin layer, and then the conductive layer undergoes etching to thereby form the inner circuit patterns 12 and 13.

When the first layer 10 is a ceramic layer, ceramic green sheets are stacked, and conductive materials are then printed on the stack of sheets, thereby forming an inner layer circuit pattern.

Then, as shown in FIG. 4B, the first resistor 11 is formed so that both ends of the first resistor 11 are connected to the first and second inner layer pads 12a and 12b. The first resistor 11 may be formed of resistive materials, such as carbon. The first resistor 11 may be formed by general screen printing using these resistive materials.

As shown in FIG. 4C, the second layer 20 is then formed using insulating materials on the first layer 10. The second layer 20 is provided as an outer layer of the main body of the multilayer wiring board.

Then, as shown in FIG. 4D, via holes h connected to the first and second inner layer pads 12a and 12b are formed in the second layer 20. A method of forming the via holes h is not particularly limited. For example, the via holes h may be formed by a drilling process.

As shown in FIG. 4E, via holes h are filled, and the outer layer circuit pattern 22 including the first and second outer pads 22a and 22b is formed on the second layer 20. The outer layer circuit pattern 22 may be formed in the same manner as the inner layer circuit patterns as described above.

Then, as shown in FIG. 4F, the second resistor 21 is formed so that both ends of the second resistor 21 are connected to the first and second outer pads 22a and 22b. The second resistor 21 is formed to have a smaller area than the first resistor 11. In FIG. 4F, a longitudinal direction of the second resistor 21 is shown. The second resistor 21 has the same length as the first resistor 11 and a smaller width than the first resistor 11.

The second resistor 21 may have a greater resistance value than the first resistor 11. The resistance value may be adjusted by controlling the materials forming the resistor. When the first and second resistors 11 and 21 are formed of the same materials, the second resistor 21 is formed to have a smaller area than the first resistor 11 and thus has a greater resistance value than the first resistor.

Alternatively, irrespective of the above-described order, the first and second resistors may be formed on the first and second layers, respectively, and the first and second layers may be then stacked so that the first and second resistors are connected in parallel with each other.

Though not shown, the first and second resistors may be connected in parallel with each other through an electrical connection between one region of the inner layer circuit pattern connected to the first resistor and one region of the outer layer circuit pattern connected to the second resistor as well as through an electrical connection between the inner and outer pads connected to both ends of each of the first and second resistors.

The second resistor 21 may undergo a process of adjusting a resistance value. In general, when a resistor is printed and is subject to sintering, manufacturing tolerances occur. In particular, since a ceramic substrate is more likely to be subject to manufacturing tolerances according to a sintering process, a method of adjusting a resistance value through the second resistor 21 can be usefully applied.

The resistance adjustment portion of the second resistor 21 is not particularly limited. For example, the resistance value may be adjusted by performing a trimming process on the second resistor.

More specifically, the second resistor 21 is formed to have a smaller value than the target resistance value. Then, probes connected to a resistance measurement device are connected to electrodes of both ends of the second resistor 21 to measure a resistance value in real time, and at the same time, performing laser machining on the resistor to thereby obtain a target resistance value.

Though not shown in the drawings, the third layer 30 may be further formed as an outer layer on the side of the second layer 20, where the second resistor 21 is not formed. In this case, the multilayer wiring board having the configuration, shown in FIG. 2, may be manufactured. As described above, an outer layer circuit pattern 32 may also be formed on the third layer 30.

As set forth above, according to exemplary embodiments of the invention, a multilayer wiring board obtains a target resistance value using first and second resistors formed on the inner and outer layers. The second resistor, formed on the outer layer, can have a smaller area than the first resistor to thereby increase the usable area of the outer layer. That is, the area of the outer layer on which other elements are mounted is increased to thereby improve the area utilization of the substrate and reduce the size of the multilayer wiring board.

Furthermore, currents flowing through the multilayer wiring board spread to the first and second resistors to thereby prevent the deterioration of the resistors.

While the present invention has been shown and described in connection with the exemplary embodiments, it will be apparent to those skilled in the art that modifications and variations can be made without departing from the spirit and scope of the invention as defined by the appended claims.

What is claimed is:

1. A multilayer wiring board comprising:
a main body having a plurality of insulting layers stacked upon each other, including a first layer provided as an inner layer and a second layer provided as an outer layer;
a first resistor provided on the first layer; and
a second resistor provided on the second layer, connected in parallel with the first resistor, and having a smaller area than the first resistor.

2. The multilayer wiring board of claim 1, wherein the second resistor has a greater resistance value than the first resistor.

3. The multilayer wiring board of claim 1, wherein the second resistor has a resistance value adjustment portion.

4. The multilayer wiring board of claim 1, wherein the first layer comprises an inner layer circuit pattern electrically connected to the first resistor, the second resistor comprises an outer layer circuit pattern electrically connected to the second resistor, and the inner layer circuit pattern and the outer layer circuit pattern are electrically connected to each other through via holes.

5. A method of manufacturing a multilayer wiring board, the method comprising:
providing a plurality of insulating layers forming a main body;
forming a first resistor on a first layer provided as an inner layer among the insulating layers;
forming a second resistor on a second layer provided as an outer layer among the insulating layers while the second resistor has a smaller area than the first resistor; and
stacking the first and second layers so that the first and second resistors are connected in parallel with each other.

6. The method of claim 5, wherein the second resistor has a greater resistance value than the first resistor.

7. The method of claim 5, further comprising obtaining a target resistance value by trimming the second resistor after stacking of the first and second layers.
